(19) United States
(12) Patent Application Publication
(10) Pub. No.: US 2025/0015200 A1
(43) Pub. Date: Jan. 9, 2025

(54) SEMICONDUCTOR DEVICE AND METHOD OF MANUFACTURING THE SAME

(71) Applicant: Renesas Electronics Corporation, Tokyo (JP)

(72) Inventor: Keiichi FURUYA, Tokyo (JP)

(21) Appl. No.: 18/666,131

(22) Filed: May 16, 2024

(30) Foreign Application Priority Data
Jul. 5, 2023 (JP) 2023-110639

(51) Int. Cl. H01L 29/866; H01L 21/8234; H01L 27/06; H01L 27/08; H01L 29/66

(52) U.S. Cl. CPC H01L 29/866; H01L 21/823493; H01L 27/0629; H01L 27/0814; H01L 29/66106

(57) ABSTRACT

A semiconductor substrate includes a p-type substrate body, an n-type buried layer on the p-type substrate body, and a p-type semiconductor layer on the n-type buried layer. A DTI region penetrates through the p-type semiconductor layer and the n-type buried layer, and reaches the p-type substrate body. An n-type semiconductor region, which is a cathode region of a Zener diode, and a p-type anode region of the Zener diode are formed in the semiconductor layer. The p-type anode region includes a p-type first semiconductor region formed under the n-type semiconductor region, and a p-type second semiconductor region formed under the p-type first semiconductor region. A PN junction is formed between the p-type first semiconductor region and the n-type semiconductor region. An impurity concentration of the p-type second semiconductor region is higher than an impurity concentration of the p-type first semiconductor region.

### CROSS-REFERENCE TO RELATED APPLICATIONS

The disclosure of Japanese Patent Application No. 2023-110639 filed on Jul. 5, 2023, including the specification, drawings and abstract is incorporated herein by reference in its entirety.

### BACKGROUND

The present invention relates to a semiconductor device and a method of manufacturing the same, for example, it can be suitably used for a semiconductor device including a Zener diode and a method of manufacturing the same.

There is a disclosed technique listed below.
[Patent Document 1] Japanese Unexamined Patent Application Publication No. 2013-183039
Patent Document 1 discloses a semiconductor device including a Zener diode.

### SUMMARY

Improving performance is desirable in a semiconductor device including a Zener diode.

Other objects and novel features will become apparent from the description of this specification and the accompanying drawings. According to one embodiment, a semiconductor device includes a semiconductor substrate and an element isolation region. The semiconductor substrate includes a substrate region of a first conductivity type, a first semiconductor layer of a second conductivity type formed on the substrate region, and a second semiconductor layer of the first conductivity type formed on the first semiconductor layer. The element isolation region penetrates through the second semiconductor layer and the first semiconductor layer and reaches the substrate region. A cathode region of the second conductivity type and an anode region of the first conductivity type of the Zener diode are formed in the second semiconductor layer. The anode region includes a first semiconductor region of the first conductivity type formed under the cathode region and a second semiconductor region of the first conductivity type formed under the first semiconductor region. A PN junction is formed between the first semiconductor region and the cathode region. An impurity concentration of the second semiconductor region is higher than an impurity concentration of the first semiconductor region.

According to one embodiment, the performance of the semiconductor device can be improved.

### BRIEF DESCRIPTION OF THE DRAWINGS

FIG. 1 is a main portion cross-sectional view of a semiconductor device in a first embodiment.

FIG. 2 is a main portion cross-sectional view in the manufacturing step of the semiconductor device in the first embodiment.

FIG. 3 is a main portion cross-sectional view in the manufacturing step of the semiconductor device following FIG. 2.

FIG. 4 is a main portion cross-sectional view in the manufacturing step of the semiconductor device following FIG. 3.

FIG. 5 is a main portion cross-sectional view in the manufacturing step of the semiconductor device following FIG. 4.

FIG. 6 is a main portion cross-sectional view in the manufacturing step of the semiconductor device following FIG. 5.

FIG. 7 is a main portion cross-sectional view in the manufacturing step of the semiconductor device following FIG. 6.

FIG. 8 is a main portion cross-sectional view in the manufacturing step of the semiconductor device following FIG. 7.

FIG. 9 is a main portion cross-sectional view in the manufacturing step of the semiconductor device following FIG. 8.

FIG. 10 is a main portion cross-sectional view in the manufacturing step of the semiconductor device following FIG. 9.

FIG. 11 is a main portion cross-sectional view in the manufacturing step of the semiconductor device following FIG. 10.

FIG. 12 is a main portion cross-sectional view in the manufacturing step of the semiconductor device following FIG. 11.

FIG. 13 is a main portion cross-sectional view in the manufacturing step of the semiconductor device following FIG. 12.

FIG. 14 is a main portion cross-sectional view of a semiconductor device in a first examined example.

FIG. 15 is a main portion cross-sectional view of a semiconductor device in a second examined example.

FIG. 16 is a main portion cross-sectional view of a semiconductor device in a third examined example.

FIG. 17 is an explanatory diagram of the semiconductor device in the first embodiment.

FIG. 18 is a graph showing the operating characteristics of the Zener diode in the first examined example.

FIG. 19 is a graph showing the operating characteristics of the Zener diode in the first embodiment.

FIG. 20 is a main portion cross-sectional view of a semiconductor device in a second embodiment.

FIG. 21 is a main portion cross-sectional view of a semiconductor device in a third embodiment.

FIG. 22 is a main portion cross-sectional view of a semiconductor device in a fourth embodiment.

FIG. 23 is an explanatory diagram showing an example of use of the semiconductor device.

FIG. 24 is an explanatory diagram showing an example of use of the semiconductor device.

FIG. 25 is an explanatory diagram showing an example of use of the semiconductor device.

FIG. 26 is an explanatory diagram showing an example of use of the semiconductor device.

### DETAILED DESCRIPTION

In the following embodiments, when required for convenience, the description will be made by dividing into a plurality of sections or embodiments, but except when specifically stated, they are not independent of each other, and one is related to the modified example, detail, supplementary description, or the like of part or all of the other. In the following embodiments, the number of elements, etc. (including the number of elements, numerical values, quantities, ranges, etc.) is not limited to the specific number, but may be not less than or equal to the specific number, except for cases where the number is specifically indicated and is clearly limited to the specific number in principle.

Furthermore, in the following embodiments, it is needless to say that the constituent elements (including element steps and the like) are not necessarily essential except in the case where they are specifically specified and the case where they are considered to be obviously essential in principle. Similarly, in the following embodiments, when referring to the shapes, positional relationships, and the like of components and the like, it is assumed that the shapes and the like are substantially approximate to or similar to the shapes and the like, except for the case in which they are specifically specified and the case in which they are considered to be obvious in principle, and the like. The same applies to the above numerical values and ranges.

Hereinafter, embodiments are described in detail with reference to the drawings. In all the figures for explaining the embodiments, the same reference numerals are given to the members having the same functions, and the description of the repetition is omitted. In the following embodiments, descriptions of the same or similar parts will not be repeated in principle except when particularly necessary.

In the drawings used in the embodiments, hatching may be omitted even in the case of cross-sectional view in order to make the drawings easier to see. Also, even in the case of a plan view, hatching may be used to make the drawing easier to see.

Also, a plan view corresponds to a view from a plane substantially parallel to a main surface or a back surface of a semiconductor substrate SUB. Also, the bottom surface and the lower surface have the same meaning. Also, the height position corresponds to the distance from the back surface of the semiconductor substrate SUB. Also, the depth position corresponds to the distance from the main surface of the semiconductor substrate SUB.

In this application, MOSFET (Metal Oxide Semiconductor Field Effect Transistor) or LDMOSFET (Laterally Diffused Metal Oxide Semiconductor Field Effect Transistor) includes not only MOSFETs using an oxide film as a gate dielectric film, but also MOSFETs using a dielectric film other than an oxide film as a gate dielectric film. The LDMOSFET may also be referred to as HV-MOSFET (High Voltage Metal Oxide Semiconductor Field Effect Transistor) or DEMOSFET (Drain Extended Metal Oxide Semiconductor Field Effect Transistor).

### First Embodiment

### Structure of Semiconductor Device

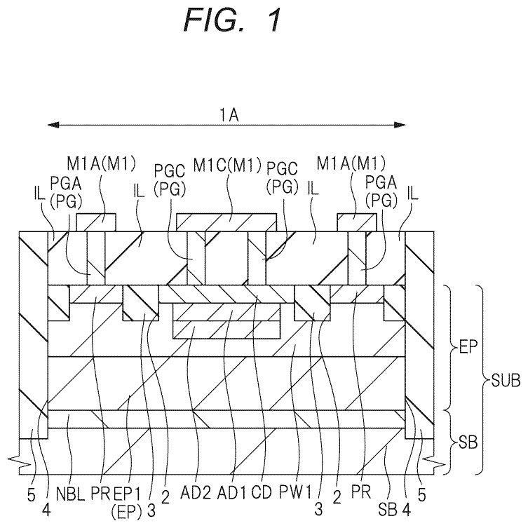

The semiconductor device of the present embodiment will be described with reference to the drawings. FIG. 1 is a main portion cross-sectional view of a semiconductor device according to the present embodiment.

As shown in FIG. 1, the semiconductor device of the present embodiment includes the semiconductor substrate SUB, an STI region 3, a DTI region 5, a p-type well PW1, a p-type semiconductor region AD1, a p-type semiconductor region AD2, a p-type semiconductor region PR, and an n-type semiconductor region CD.

As shown in FIG. 1, the semiconductor substrate SUB includes a p-type substrate body SB, an n-type buried layer NBL formed on the p-type substrate body SB, and a p-type semiconductor layer EP formed on the n-type buried layer NBL.

The p-type substrate body SB is made of, for example, p-type monocrystalline silicon into which a p-type impurity such as boron (B) is introduced. The n-type buried layer NBL is an n-type semiconductor layer. The n-type buried layer NBL is formed in a layer in an upper portion of the p-type substrate body SB. The p-type substrate body SB under the n-type buried layer NBL is a p-type substrate region. The p-type semiconductor layer EP is made of, for example, p-type monocrystalline silicon formed by epitaxial growth on the n-type buried layer NBL.

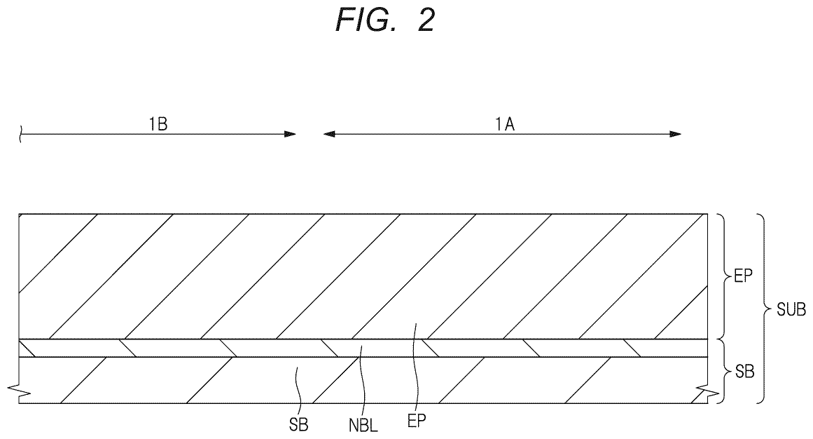

Here, the semiconductor substrate SUB includes a Zener diode formation region 1A and a transistor formation region 1B. The Zener diode formation region 1A includes a Zener diode. The transistor formation region 1B includes a transistor element. The Zener diode formation region 1A and the transistor formation region 1B are disposed at different positions at the main surface of the semiconductor substrate SUB. A cross-sectional view of the Zener diode formation region 1A is shown in FIG. 1. Cross-sectional views of the Zener diode formation region 1A and the transistor formation region 1B are shown in FIGS. 2 to 13, which will be described later.

The main surface of the semiconductor substrate SUB corresponds to the main surface of the semiconductor layer EP. Also, the back surface of the semiconductor substrate SUB corresponds to the back surface of the p-type substrate body SB. The main surface of the semiconductor substrate SUB and the back surface of the semiconductor substrate SUB are located on opposite sides of each other.

At the main surface of the semiconductor substrate SUB, the STI (Shallow Trench Isolation) region 3 is formed. The STI region 3 is formed of a dielectric film such as a silicon oxide film embedded in a trench 2 formed in the semiconductor layer EP.

Also, at the main surface of the semiconductor substrate SUB, the DTI (Deep Trench Isolation) region 5 is formed. The DTI region 5 is formed of a dielectric film such as a silicon oxide film embedded in a trench 4 formed in a dielectric film IL on the semiconductor substrate SUB and in the semiconductor substrate SUB. The DTI region 5 functions as an element isolation region.

The depth of the DTI region 5 is deeper than the depth of the STI region 3. That is, the height position of the bottom surface of the DTI region 5 is lower than the height position of the bottom surface of the STI region 3. The STI region 3 does not reach the n-type buried layer NBL. The DTI region 5 penetrates through the semiconductor layer EP and the n-type buried layer NBL, and reaches the p-type substrate body SB. The bottom surface of the DTI region 5 is located halfway through the thickness of the p-type substrate body SB.

In the present embodiment, the trench 4 and the DTI region 5 penetrate through the dielectric film IL, a part of the DTI region 5 is located in the trench 4 of the dielectric film IL, and another part of the DTI region 5 is located in the trench 4 of the semiconductor substrate SUB. The trench 4 may be formed in the semiconductor substrate SUB without penetrating through the dielectric film IL. In that case, the DTI region 5 is embedded in the trench 4 of the semiconductor substrate SUB, and the height position of the upper surface of the DTI region 5 is approximately the same as the height position of the main surface of the semiconductor substrate SUB.

In plan view, the DTI region 5 is disposed so as to surround the Zener diode formation region 1A. That is, in plan view, the semiconductor layer EP and the n-type buried layer NBL in the Zener diode formation region 1A are surrounded by the DTI region 5. The DTI region 5 electrically isolates the semiconductor layer EP and the n-type buried layer NBL in the Zener diode formation region 1A from the semiconductor layer EP and the n-type buried layer NBL located outside the Zener diode formation region 1A.

The p-type well region PW1, the p-type semiconductor region AD1, the p-type semiconductor region AD2, the p-type semiconductor region PR, and the n-type semiconductor region CD are formed in the semiconductor substrate SUB. Specifically, in the Zener diode formation region 1A, the p-type well region PW1 is formed in the semiconductor layer EP. The p-type semiconductor region AD1, the p-type semiconductor region AD2, the p-type semiconductor region PR, and the n-type semiconductor region CD are formed in the p-type well region PW1.

The p-type well region PW1 is formed in the upper portion of the semiconductor layer EP. The p-type semiconductor layer EP interposed between the bottom surface of the p-type well region PW1 and the upper surface of the n-type buried layer NBL is the p-type semiconductor region EP1.

The n-type semiconductor region CD is formed in the upper portion of the p-type well region PW1. The n-type semiconductor region CD is in contact with the main surface of the semiconductor substrate SUB and is formed to a predetermined depth from the main surface of the semiconductor substrate SUB. The n-type semiconductor region CD functions as the n-type cathode region of the Zener diode.

The p-type semiconductor region AD1 is formed under the n-type semiconductor region CD. The p-type semiconductor region AD2 is formed under the p-type semiconductor region AD1. The p-type impurity concentration of the p-type semiconductor region AD2 is higher than the p-type impurity concentration of the p-type semiconductor region AD1. The p-type impurity concentration of the p-type semiconductor region AD1 is higher than the p-type impurity concentration of the p-type well region PW1. The p-type impurity concentration of the p-type well region PW1 is higher than the p-type impurity concentration of the p-type semiconductor layer EP under the p-type well region PW1. In other words, the p-type impurity concentration of the p-type well region PW1 is higher than the p-type impurity concentration of the p-type semiconductor region EP1. The p-type semiconductor region AD1, the p-type semiconductor region AD2, and the p-type well PW1 are electrically connected to one another.

In the direction from the main surface to the back surface of the semiconductor substrate SUB, the n-type semiconductor region CD and the p-type semiconductor region AD1 are adjacent to each other, and a PN junction is formed between the n-type semiconductor region CD and the p-type semiconductor region AD1.

In the direction from the main surface to the back surface of the semiconductor substrate SUB, the p-type semiconductor region AD1 and the p-type semiconductor region AD2 are adjacent to each other. The planar dimensions (area) of the p-type semiconductor region AD1 and the p-type semiconductor region AD2 may be approximately the same, but may also be different. In plan view, the p-type semiconductor region AD1 and the p-type semiconductor region AD2 overlap each other.

Also, in plan view, the n-type semiconductor region CD includes the p-type semiconductor region AD1, and the planar dimension of the p-type semiconductor region AD1 is smaller than the planar dimension of the n-type semiconductor region CD.

Therefore, the central portion of the bottom surface of the n-type semiconductor region CD contacts the p-type semiconductor region AD1, and the peripheral portion of the bottom surface of the n-type semiconductor region CD contacts the p-type well region PW1. In other words, the central portion of the bottom surface of the n-type semiconductor region CD is covered by the p-type semiconductor region AD1, and the peripheral portion of the bottom surface of the n-type semiconductor region CD is covered by the p-type well region PW1. A PN junction is also formed between the n-type semiconductor region CD and the p-type well region PW1.

The depth of the bottom surface of the p-type semiconductor region AD2 is shallower than the depth of the bottom surface of the p-type well region PW1. The side surface of the p-type semiconductor region AD1, the side surface of the p-type semiconductor region AD2, and the bottom surface of the p-type semiconductor region AD2 are covered by the p-type well region PW1.

The p-type semiconductor region formed of the p-type semiconductor region AD1, the p-type semiconductor region AD2, and the p-type well region PW1, functions as the p-type anode region of the Zener diode. The PN junction surface formed at the interface between the n-type cathode region and the p-type anode region is configured by the PN junction surface between the n-type semiconductor region CD and the p-type semiconductor region AD1 and the PN junction surface between the n-type semiconductor region CD and the p-type well region PW1. In plan view, the PN junction surface between the n-type semiconductor region CD and the p-type semiconductor region AD1 is surrounded by the PN junction surface between the n-type semiconductor region CD and the p-type well region PW1.

Since the p-type impurity concentration of the p-type semiconductor region AD1 is higher than the p-type impurity concentration of the p-type well region PW1, the breakdown of the Zener diode occurs at the PN junction between the n-type semiconductor region CD and the p-type semiconductor region AD1. Therefore, the withstand voltage of the Zener diode is determined by the PN junction between the n-type semiconductor region CD and the p-type semiconductor region AD1.

The p-type semiconductor region PR is formed in the upper portion of the p-type well region PW1. The p-type semiconductor region PR contacts the main surface of the semiconductor substrate SUB and is formed to a predetermined depth from the main surface of the semiconductor substrate SUB. In plan view, the p-type semiconductor region PR is formed, for example, to surround the n-type semiconductor region CD. The p-type semiconductor region PR and the n-type semiconductor region CD are disposed so as not to overlap each other in plan view. The depth of the bottom surface of the p-type semiconductor region PR is shallower than the depth of the bottom surface of the p-type well PW1. The bottom surface of the p-type semiconductor region PR is covered by the p-type well PW1. The p-type impurity concentration of the p-type semiconductor region PR is higher than the p-type impurity concentration of the p-type well region PW1.

Also, in plan view, the STI region 3 is disposed between the n-type semiconductor region CD and the p-type semiconductor region PR. Therefore, the side surface of the n-type semiconductor region CD and the side surface of the p-type semiconductor region PR are covered by the STI region 3.

Also, a back surface electrode (not shown) may be formed on the back surface of the semiconductor substrate SUB. The back surface electrode can supply, for example, a ground potential to the substrate body SB.

As shown in FIG. 1, the semiconductor device of the present embodiment further includes the dielectric film IL, a plurality of plugs PG, and a plurality of wirings Ml.

The dielectric film IL is formed on the main surface of the semiconductor substrate SUB. The dielectric film IL1 is formed of, for example, a laminated film of a silicon nitride film and a silicon oxide film on the silicon nitride film. A plurality of contact holes are formed in the dielectric film IL, and the plurality of conductive plugs PG are formed in the plurality of contact holes. The plurality of plugs PG include a plug PGA and a plug PGC. The plug PGA is disposed on the p-type semiconductor region PR and is electrically connected to the p-type semiconductor region PR. The plug PGC is disposed on the n-type semiconductor region CD and is electrically connected to the n-type semiconductor region CD.

Furthermore, a metal silicide layer (not shown) can be formed on the n-type semiconductor region CD and the p-type semiconductor region PR. In this case, the plug PGC contacts the metal silicide layer on the n-type semiconductor region CD and is electrically connected to the n-type semiconductor region CD via the metal silicide layer. Also, the plug PGA contacts the metal silicide layer on the p-type semiconductor region PR and is electrically connected to the p-type semiconductor region PR via the metal silicide layer.

The plurality of wirings Ml are formed on the dielectric film IL. The plurality of wirings Ml include an anode wiring M1A and a cathode wiring M1C. The cathode wiring M1C is electrically connected to the n-type semiconductor region CD via the plug PGC. A cathode potential is supplied to the n-type cathode region of the Zener diode via the plug PGC from the cathode wiring M1C. The anode wiring M1A is electrically connected to the p-type semiconductor region PR via the plug PGA, and further electrically connected to the p-type well region PW1 via the p-type semiconductor region PR. An anode potential is supplied to the p-type anode region of the Zener diode via the plug PGA from the anode wiring M1A.

The illustration and description of the structure above the dielectric film IL and the wiring Ml are omitted.

In the present embodiment, the n-type cathode region and the p-type cathode region of the Zener diode are formed in the semiconductor layer EP in the Zener diode formation region 1A surrounded by the DTI region 5 and the n-type buried layer NBL. Therefore, the Zener diode formed in the semiconductor substrate SUB can be electrically isolated from other semiconductor elements formed in the semiconductor substrate SUB. The other semiconductor elements formed in the semiconductor substrate SUB are, for example, transistor elements formed in the transistor formation region 1B.

### Manufacturing Step of Semiconductor Device

The manufacturing steps of the semiconductor device of the present embodiment will be described with reference to the drawings. FIGS. 2 to 13 are main portion cross-sectional views in the manufacturing steps of the semiconductor device of the present embodiment.

First, as shown in FIG. 2, the semiconductor substrate SUB having the p-type substrate body SB, the n-type buried layer NBL on the p-type substrate body SB, and the p-type semiconductor layer EP on the n-type buried layer NBL is prepared. The p-type substrate body SB is formed of, for example, p-type monocrystalline silicon.

As shown in FIG. 2, the n-type buried layer NBL is formed adjacent to the interface between the substrate body SB and the semiconductor layer EP. The n-type buried layer NBL can be formed before the formation of the semiconductor layer EP. For example, after forming the n-type buried layer NBL in the surface layer of the p-type substrate body SB by ion implantation, the p-type semiconductor layer EP can be formed on the n-type buried layer NBL by an epitaxial growth method.

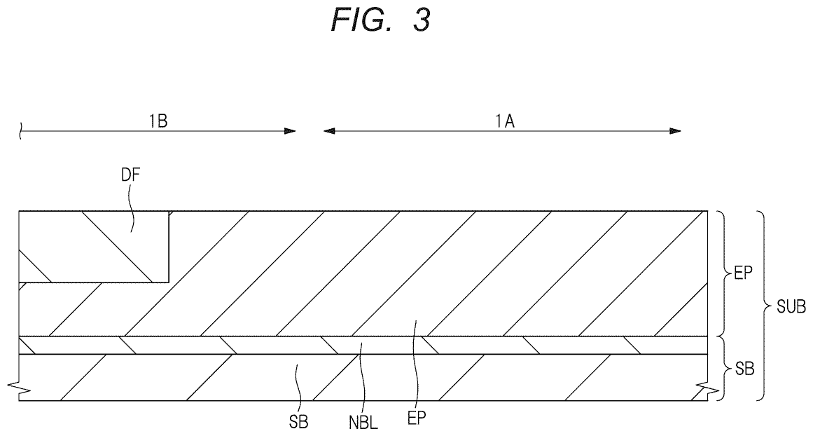

Next, as shown in FIG. 3, an n-type drift region DF is formed in the semiconductor layer EP in the transistor formation region 1B using a method such as ion implantation. The n-type drift region DF is an n-type semiconductor region.

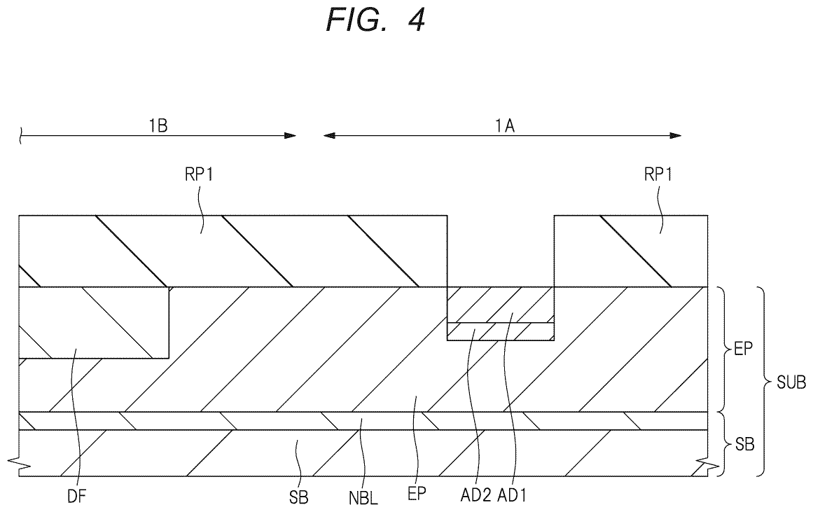

Next, as shown in FIG. 4, a photoresist pattern RP1 is formed on the main surface of the semiconductor substrate SUB.

Next, by using the photoresist pattern RP1 as a mask layer and performing a step of ion-implanting p-type impurities into the semiconductor layer EP in the Zener diode formation region 1A twice, the p-type semiconductor region AD1 and the p-type semiconductor region AD2 are formed.

By the first ion implantation step, the p-type semiconductor region AD2 is formed, and by the second ion implantation step, the p-type semiconductor region AD1 is formed. The implantation energy of the first ion implantation step is greater than the implantation energy of the second ion implantation step. For example, the implantation energy of the first ion implantation step is, for example, 200 keV, and the implantation energy of the second ion implantation step is, for example, 50 keV. Also, the dose amount of the first ion implantation step is greater than the dose amount of the second ion implantation step.

The p-type impurity concentration of the p-type semiconductor region AD2 is higher than the p-type impurity concentration of the p-type semiconductor region AD1, and the p-type semiconductor region AD2 is located under the p-type semiconductor region AD1.

In the present embodiment, the p-type semiconductor region AD2 is formed by the first ion implantation step, and the p-type semiconductor region AD1 is formed by the second ion implantation step, but the p-type semiconductor region AD1 can also be formed by the first ion implantation step, and the p-type semiconductor region AD2 can be formed by the second ion implantation step. In that case, the implantation energy of the second ion implantation step is greater than the implantation energy of the first ion implantation step, and the dose amount of the second ion implantation step is greater than the dose amount of the first ion implantation step.

In this way, the p-type semiconductor region AD2 is formed by ion implantation with a larger implantation energy and dose than the ion implantation that forms the p-type semiconductor region AD1. This allows the p-type semiconductor region AD2, which has a higher p-type impurity concentration than the p-type semiconductor region AD1, to be formed at a deeper position than the p-type semiconductor region AD1. Therefore, the p-type semiconductor region AD2, which has a higher p-type impurity concentration than the p-type semiconductor region AD1, is located under the p-type semiconductor region AD1.

Also, each of the p-type semiconductor region AD1 and the p-type semiconductor region AD2 is formed by ion implantation using the photoresist pattern RP1 as a mask layer. Therefore, the planar dimensions (area) of the p-type semiconductor region AD1 and the p-type semiconductor region AD2 are almost the same, but may be different. In plan view, the p-type semiconductor region AD1 and the p-type semiconductor region AD2 overlap each other.

Subsequently, the photoresist pattern RP1 is removed by ashing or the like.

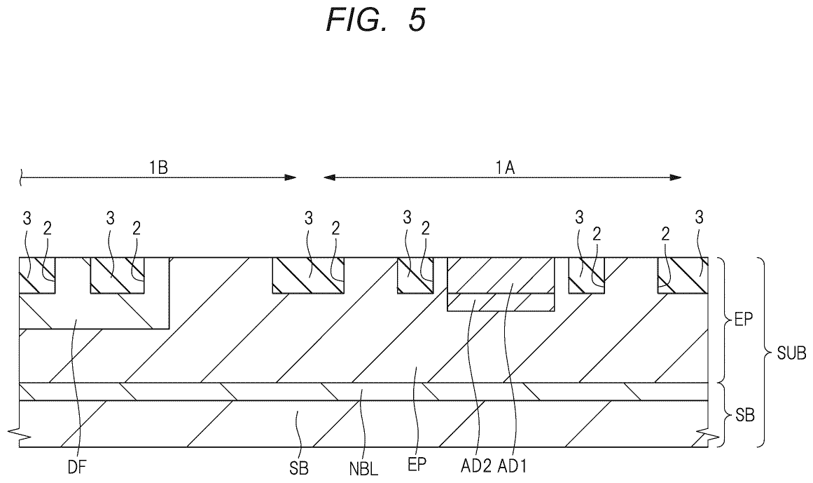

Next, as shown in FIG. 5, the STI region 3 is formed using the STI method.

After forming the trench 2 at the main surface of the semiconductor substrate SUB, a dielectric film made of silicon oxide or the like is formed on the main surface of the semiconductor substrate SUB so as to fill the trench 2. Subsequently, the dielectric film located outside the trench 2 is removed using a method such as CMP (Chemical Mechanical Polishing). This allows the formation of the STI region 3 made of the dielectric film embedded in the trench 2.

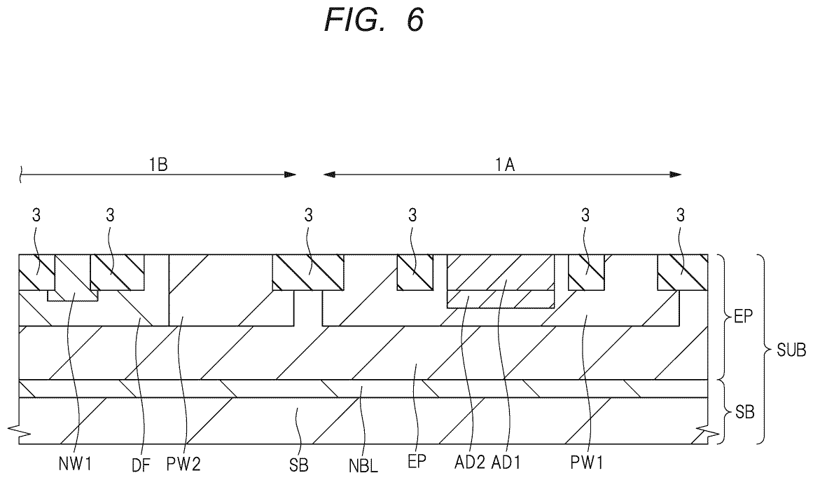

Next, as shown in FIG. 6, an n-type semiconductor region NW1 is formed in the semiconductor layer EP in the transistor formation region 1B using a method such as ion implantation.

Next, as shown in FIG. 6, p-type well region PW1 and a p-type well region PW2 are formed using a method such as ion implantation. The p-type well region PW1 and the p-type well region PW2 are each a p-type semiconductor region. In the Zener diode formation region 1A, the p-type well region PW1 is formed in the semiconductor layer EP. In the transistor formation region 1B, the p-type well region PW2 is formed in the semiconductor layer EP.

The p-type well region PW1 is formed over a predetermined depth from the main surface of the semiconductor substrate SUB. Also, the p-type well region PW1 is formed so as to include the p-type semiconductor region AD1 and the p-type semiconductor region AD2 in plan view. The depth of the bottom surface of the p-type well region PW1 is deeper than the depth of the bottom surface of the p-type semiconductor region AD2. Therefore, each side surface of the p-type semiconductor region AD1, the side surface of the p-type semiconductor region AD2 and the bottom surface of the p-type semiconductor region AD2 are covered by the p-type well region PW1. The p-type impurity concentration of each of the p-type semiconductor region AD1 and the p-type semiconductor region AD2 is higher than the p-type impurity concentration of the p-type well region PW1.

The p-type well region PW1 and the p-type well region PW2 can be formed by the same ion implantation step to reduce the number of manufacturing steps, but they can also be formed by separate ion implantation steps.

In the present embodiment, the p-type well region PW1 and the p-type well region PW2 are formed after forming the n-type semiconductor region NW1, but the n-type semiconductor region NW1 can also be formed after forming the p-type well region PW1 and the p-type well region PW2.

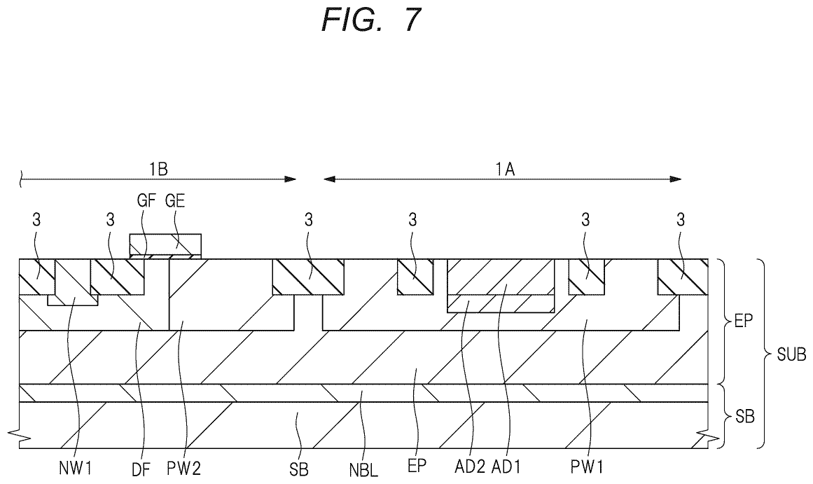

Next, as shown in FIG. 7, a gate electrode GE is formed on the main surface of the semiconductor layer EP in the transistor formation region 1B via a gate dielectric film GF.

The gate electrode GE is formed of, for example, a polycrystalline silicon film. The gate dielectric film GF is formed of, for example, a silicon oxide film.

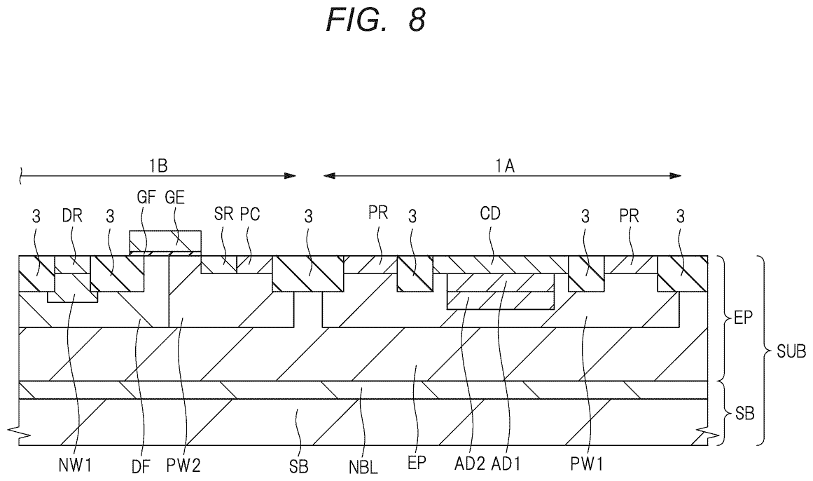

Next, as shown in FIG. 8, the n-type semiconductor region CD, an n-type source region SR, and an n-type drain region DR are formed using methods such as ion implantation. The n-type source region SR functions as a source region of the LDMOSFET. The n-type drain region DR functions as a drain region of the LDMOSFET.

In the Zener diode formation region 1A, the n-type semiconductor region CD is formed in the semiconductor layer EP. The n-type semiconductor region CD is formed over a predetermined depth from the main surface of the semiconductor substrate SUB. By forming the n-type semiconductor region CD, the p-type semiconductor region AD1 is located under the n-type semiconductor region CD.

In the transistor formation region 1B, the n-type drain region DR is formed in the semiconductor layer EP, more specifically, in the n-type drift region DF. The n-type impurity concentration of the n-type drain region DR is higher than the n-type impurity concentration of the n-type drift region DF. In the transistor formation region 1B, the n-type source region SR is formed in the semiconductor layer EP, more specifically, in the p-type well region PW2. The n-type semiconductor region CD, the n-type source region SR, and the n-type drain region DR can be formed by the same ion implantation step to reduce the number of manufacturing steps, but they can also be formed by separate ion implantation steps.

Next, as shown in FIG. 8, the p-type semiconductor region PR and a p-type semiconductor region PC are formed using methods such as ion implantation. The p-type well region PR is formed in the semiconductor layer EP in the Zener diode formation region 1A, more specifically, in the p-type well region PW1. In the transistor formation region 1B, the p-type well region PC is formed in the semiconductor layer EP, more specifically, in the p-type well region PW2. The p-type semiconductor region PR and the p-type semiconductor region PC can be formed by the same ion implantation step to reduce the number of manufacturing steps, but they can also be formed by separate ion implantation steps.

In the present embodiment, the p-type semiconductor region PC and the p-type semiconductor region PR are formed after forming the n-type source region SR and the n-type drain region DR, but the n-type source region SR and the n-type drain region DR can also be formed after forming the p-type semiconductor region PC and the p-type semiconductor region PR.

Also, the n-type source region SR may have an LDD (Lightly doped Drain) structure. In that case, after forming an n-type semiconductor region (not shown) for the LDD structure using ion implantation, a sidewall dielectric film (not shown) is formed on the sidewalls of the gate dielectric film GF. Then, the n-type source region SR and the n-type drain region DR are formed using ion implantation. The n-type impurity concentration of the n-type semiconductor region for the LDD structure is lower than the n-type impurity concentrations of the n-type source region SR and the n-type drain region DR, respectively.

Furthermore, after forming the n-type source region SR, the n-type drain region DR, the p-type semiconductor region PR, and the p-type semiconductor region PC, a metal silicide layer (not shown) may be formed on the n-type source region SR, the n-type drain region DR, the p-type semiconductor region PC, the gate electrode GE, the p-type semiconductor region PR, and the n-type semiconductor region CD. The metal silicide layer SL is formed using a salicide (Self Aligned Silicide) technique.

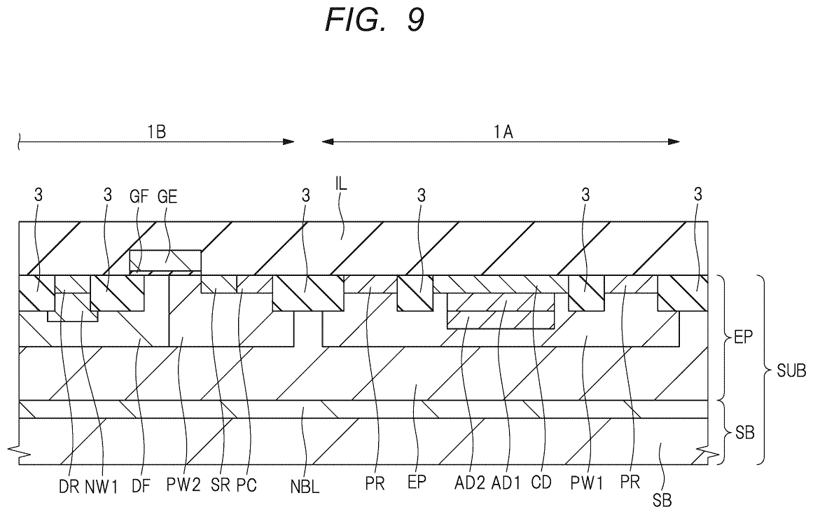

Next, as shown in FIG. 9, the dielectric film IL is formed on the main surface of the semiconductor substrate SUB to cover the gate electrode GE, using a method such as CVD (Chemical Vapor Deposition). After forming the dielectric film IL, the upper surface of the dielectric film IL can also be polished and flattened using a method such as CMP.

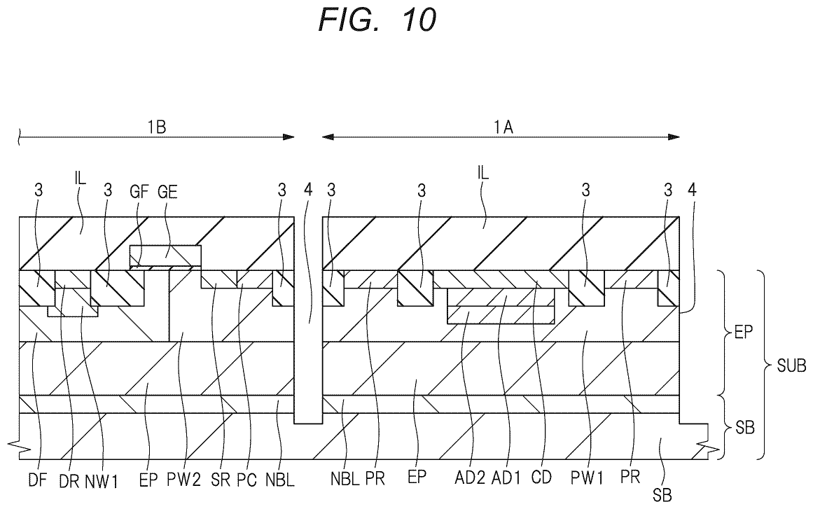

Next, as shown in FIG. 10, the trench 4 is formed by using a photoresist pattern (not shown) as an etching mask and etching the dielectric film IL, the STI region 3, and the semiconductor substrate SUB. The trench 4 penetrates through the dielectric film IL, the STI region 3, the semiconductor layer EP, and the n-type buried layer NBL, and reaches the p-type substrate body SB.

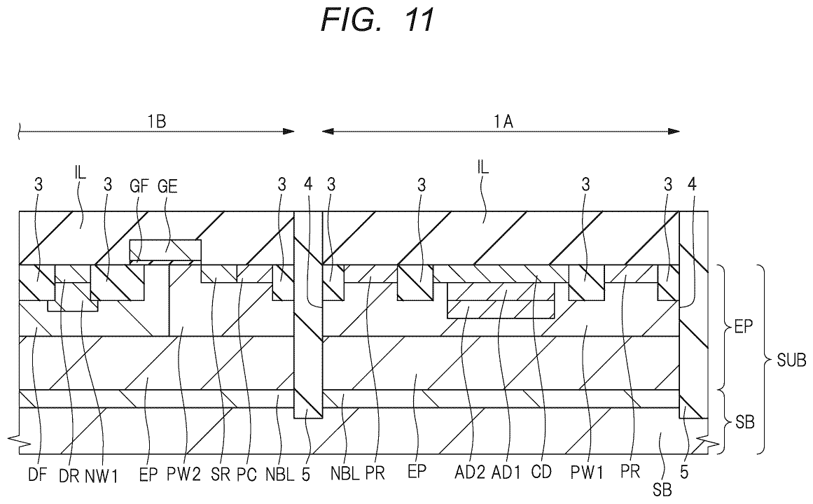

Next, as shown in FIG. 11, the DTI region 5 is formed in the trench 4.

After forming the trench 4, a dielectric film, such as a silicon oxide film, is formed on the dielectric film IL to fill the trench 4. Then, the dielectric film located outside the trench 4 is removed using a method such as CMP. This allows the formation of the DTI region 5 formed of the dielectric film embedded in the trench 4. A void may be formed in the DTI region 5. In the present embodiment, although a step of removing the dielectric film located outside the trench 4 using a method such as CMP is performed, this step may not be necessary. In that case, the dielectric film formed integrally with the DTI region 5 remains on the dielectric film IL.

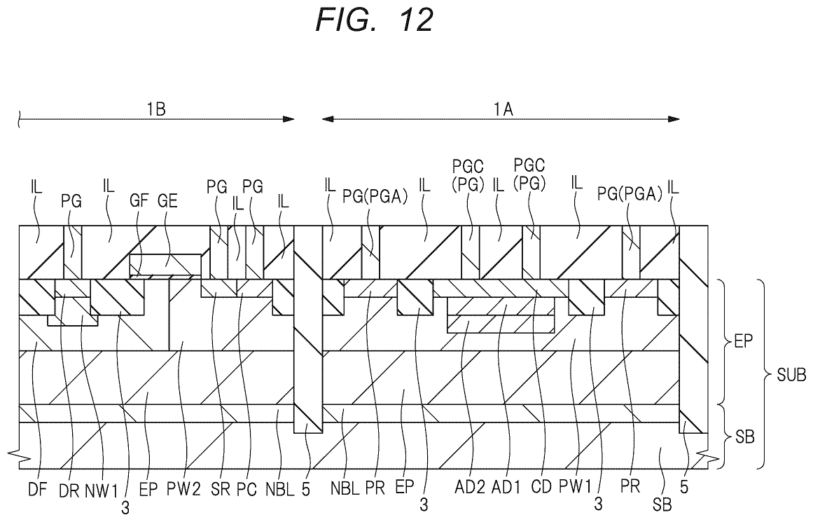

Next, as shown in FIG. 12, a plurality of contact holes penetrating through the dielectric film IL are formed by using a photoresist pattern (not shown) formed on the dielectric film IL as an etching mask and etching the dielectric film IL. Subsequently, a plurality of conductive plugs PG are respectively formed in the plurality of contact holes.

For example, a barrier conductor film is formed on the bottom surface of the contact hole, on the side surface of the contact hole, and on the upper surface of the insulating film IL. A main conductor film made of tungsten or the like is formed on the barrier conductor film so as to fill the contact hole. Subsequently, the main conductor film and the barrier conductor film located outside the contact hole are removed by a method such as CMP. This allows for the formation of the plurality of plugs PG.

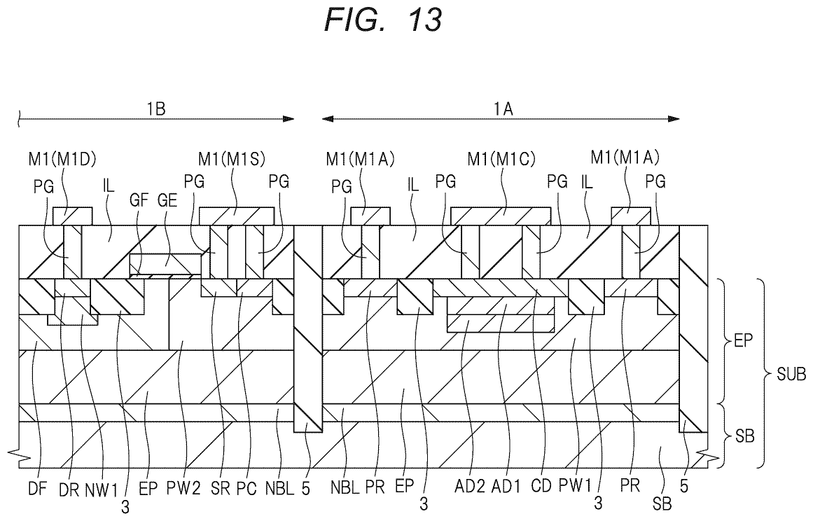

Next, as shown in FIG. 13, the plurality of wirings Ml are formed on the insulating film IL. For example, a conductive film is formed on the insulating film IL. Subsequently, by patterning the conductive film using photolithography technique and etching technique, the plurality of wirings Ml made of the conductive film can be formed. The plurality of wirings Ml are preferably aluminum wirings, but other metal material wirings, such as tungsten wiring, can also be applied. In addition, copper wiring formed using damascene technique can also be applied as the plurality of wirings Ml.

The plurality of wirings Ml have the anode wiring M1A, the cathode wiring M1C, a source wiring M1S, and a drain wiring M1D.

The drain wiring M1D is electrically connected to the n-type drain region DR via the plug PG located on the n-type drain region DR. The source wiring M1S is electrically connected to the n-type source region SR via the plug PG located on the n-type source region SR, and is also electrically connected to the p-type semiconductor region PC via the plug PG located on the p-type semiconductor region PC. Therefore, the source potential supplied to the n-type source region SR via the plug PG from the source wiring M1S is supplied to the p-type semiconductor region PC via the plug PG from the source wiring M1S, and further supplied to the p-type well region PW2 from the p-type semiconductor region PC. The source wiring M1S, the drain wiring M1D, the cathode wiring M1C, and the anode wiring M1A are not connected and are separated from each other.

The illustration and explanation of the step of forming the upper layer insulating film and wiring are omitted.

### Background of Consideration

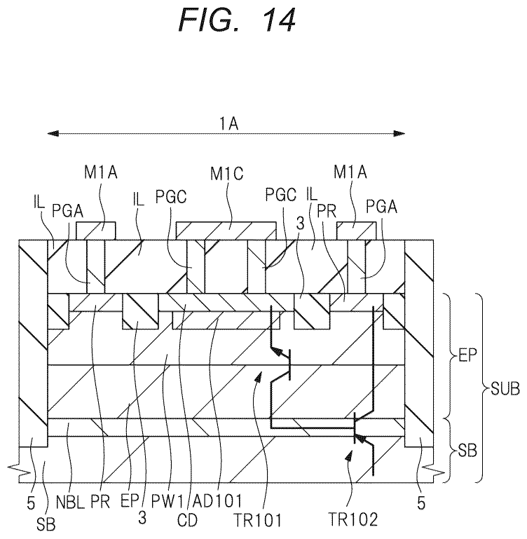

FIG. 14 is a main portion cross-sectional view of the semiconductor device of the first examined example studied by the present inventor. A cross-section corresponding to the above FIG. 1 is shown in FIG. 14. Also, FIG. 14 shows a parasitic NPN bipolar transistor TR101 and a parasitic PNP bipolar transistor TR102 formed in the semiconductor device of the first examined example.

The semiconductor device of the first examined example shown in FIG. 14 has a p-type semiconductor region AD101 instead of the p-type semiconductor region AD1 and the p-type semiconductor region AD2 shown in the above FIG. 1. As shown in FIG. 14, the p-type semiconductor region AD101 is formed under the n-type semiconductor region CD in the p-type well region PW1. The p-type impurity concentration of the p-type semiconductor region AD101 is higher than the p-type impurity concentration of the p-type well region PW1.

In the case of the first examined example, the ion implantation step of the p-type impurity using the above photoresist pattern RP1 as a mask layer is performed only once, and the p-type semiconductor region AD101 is formed by this one ion implantation step.

In the first examined example shown in FIG. 14, the n-type semiconductor region CD functions as the n-type cathode region of the Zener diode, and the p-type semiconductor region formed of the p-type semiconductor region AD101, and the p-type well region PW1 functions as the p-type anode region of the Zener diode. The withstand voltage of the Zener diode is determined by the PN junction between the n-type semiconductor region CD and the p-type semiconductor region AD101.

According to the study by the present inventor, it was found that the following problems occur in the case of the first examined example.

In the semiconductor device of the first examined example shown in FIG. 14, a parasitic thyristor formed of the parasitic NPN bipolar transistor TR101 and the parasitic PNP bipolar transistor TR102 is formed.

The n-type buried layer NBL functions as the n-type collector region of the parasitic NPN bipolar transistor TR101. The p-type semiconductor region, formed of the p-type semiconductor region AD101 and the p-type well region PW1, functions as the p-type base region of the parasitic NPN bipolar transistor TR101. The n-type semiconductor region CD functions as the n-type emitter region of the parasitic NPN bipolar transistor TR101.

Also, the p-type substrate body SB functions as the p-type collector region of the parasitic PNP bipolar transistor TR102. The n-type buried layer NBL functions as the n-type base region of the parasitic PNP bipolar transistor TR102. The p-type semiconductor region, formed of the p-type semiconductor region AD101, the p-type well region PW1, and the p-type semiconductor region PR, functions as the p-type emitter region of the parasitic PNP bipolar transistor TR102.

If a potential lower than the potential of the p-type substrate body SB is supplied to the n-type cathode region of the Zener diode, which is the n-type semiconductor region CD, and the p-type anode region, which is the p-type well region PW1, there is a risk that the aforementioned parasitic thyristor will operate. This is because if such a potential is supplied to the n-type semiconductor region CD and the p-type well region PW1, the parasitic NPN bipolar transistor TR101 will first operate, and along with it, the parasitic PNP bipolar transistor TR102 will also operate.

When the parasitic thyristor operates, electrons flow from the semiconductor layer EP to the p-type substrate body SB in the Zener diode formation region 1A. In another perspective, current flows from the p-type substrate body SB to the semiconductor layer EP in the Zener diode formation region 1A. Some of the electrons that flowed from the semiconductor layer EP to the p-type substrate body SB recombine with the holes in the p-type substrate body SB. Other parts of the electrons that flowed from the semiconductor layer EP to the p-type substrate body SB move in the p-type substrate body SB, affecting other semiconductor elements formed on the semiconductor substrate SUB, resulting in degrading the performance of the semiconductor device. In order to improve the performance of the semiconductor device, it is desirable to prevent the operation of the parasitic thyristor.

In the case of the first examined example shown in FIG. 14, it is considered that the operation of the parasitic thyristor can be suppressed by increasing the p-type impurity concentration of the p-type semiconductor region AD101. This is because if the p-type impurity concentration of the p-type semiconductor region AD101 is increased, the p-type impurity concentration of the p-type base region of the parasitic NPN bipolar transistor TR101 will increase, making it difficult for the parasitic NPN bipolar transistor TR101 to operate.

The withstand voltage of the Zener diode is determined by the PN junction between the n-type semiconductor region CD and the p-type semiconductor region AD101. And by adjusting the p-type impurity concentration of the p-type semiconductor region AD101 near the interface between the n-type semiconductor region CD and the p-type semiconductor region AD101, the withstand voltage of the Zener diode can be controlled. Therefore, the p-type impurity concentration of the p-type semiconductor region AD101 near the interface between the n-type semiconductor region CD and the p-type semiconductor region AD101 needs to be set according to the required withstand voltage of the Zener diode. The required withstand voltage of the Zener diode is the design value of the withstand voltage of the Zener diode. Therefore, since the p-type impurity concentration of the p-type semiconductor region AD101 needs to be set according to the required withstand voltage of the Zener diode, it is difficult to increase the p-type impurity concentration of the p-type semiconductor region AD101 to suppress the operation of the parasitic thyristor.

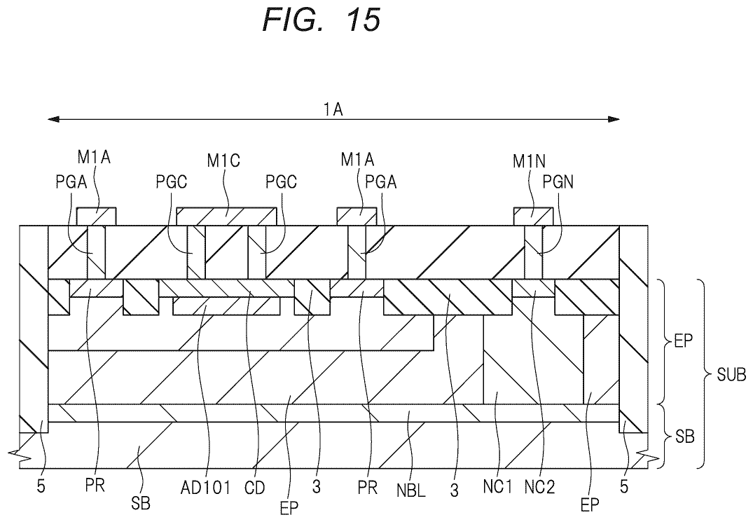

FIG. 15 is a main portion cross-sectional view of the semiconductor device of the second examined example studied by the present inventor. A cross-section corresponding to the above-mentioned FIG. 13 is shown in FIG. 15.

The semiconductor device of the second examined example shown in FIG. 15 has an n-type semiconductor region NC1, an n-type semiconductor region NC2, and a plug PGN.

The n-type semiconductor region NC1 and the n-type semiconductor region NC2 are formed in the semiconductor layer EP. The n-type semiconductor region NC1 and the n-type semiconductor region NC2 are in contact with each other. The n-type semiconductor region NC1 and the n-type buried layer NBL are in contact with each other. The plug PGN is formed on the n-type semiconductor region NC2. The n-type impurity concentration of the n-type semiconductor region NC2 is higher than the n-type impurity concentration of the n-type semiconductor region NC1. The plug PGN is electrically connected to the n-type buried layer NBL via the n-type semiconductor region NC2 and the n-type semiconductor region NC1.

In the second examined example shown in FIG. 15, it is possible to supply the same potential as the potential of the p-type substrate body SB to the n-type buried layer NBL via the plug PGN and the n-type semiconductor region NC2 and the n-type semiconductor region NC1 from the wiring M1N. Therefore, since the potential of the p-type substrate body SB and the potential of the n-type buried layer NBL are the same, it is possible to prevent the operation of the parasitic PNP bipolar transistor TR102. This can prevent the operation of the parasitic thyristor.

However, in the second examined example shown in FIG. 15, it is necessary to form the n-type semiconductor region NC1 and the n-type semiconductor region NC2 in the semiconductor layer EP. Therefore, the planar dimensions of the Zener diode formation region 1A in the second examined example become larger than the planar dimensions of the Zener diode formation region 1A in the first examined example, resulting in an increase in the planar dimensions of the semiconductor device. For the miniaturization of the semiconductor device, it is desirable not to form the n-type semiconductor region NC1 and the n-type semiconductor region NC2 in the semiconductor layer EP in the Zener diode formation region 1A.

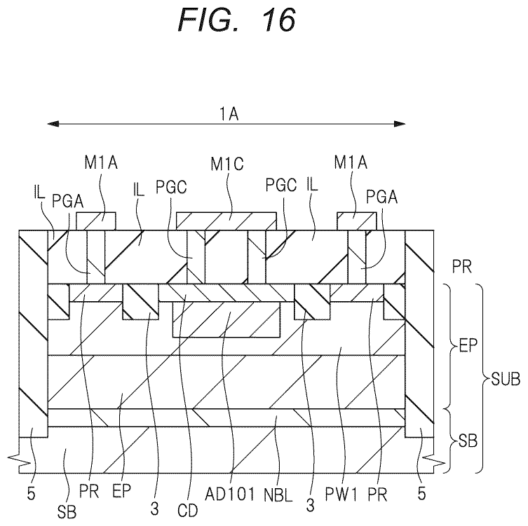

FIG. 16 is a main portion cross-sectional view of the semiconductor device of the third examined example studied by the present inventor. In FIG. 16, a cross-section corresponding to FIG. 14 is shown.

In the third examined example shown in FIG. 16, the p-type semiconductor region AD101 is formed deeper than the p-type semiconductor region AD101 in the first examined example. That is, the depth of the bottom surface of the p-type semiconductor region AD101 in the third examined example shown in FIG. 16 is deeper than the depth of the bottom surface of the p-type semiconductor region AD101 in the first examined example shown in FIG. 14. The ion implantation energy for forming the p-type semiconductor region AD101 in the third examined example is greater than the ion implantation energy for forming the p-type semiconductor region AD101 in the first examined example.

In the case of the third examined example shown in FIG. 16, the thickness of the p-type semiconductor region AD101 is greater than the thickness of the p-type semiconductor region AD101 in the first examined example. Therefore, in the case of the third examined example, compared to the first examined example, the p-type impurity concentration of the p-type base region of the parasitic NPN bipolar transistor TR101 becomes higher, making it difficult for the parasitic NPN bipolar transistor TR101 to operate. Therefore, in the case of the third examined example, it is easier to suppress the operation of the parasitic thyristor than in the first examined example.

However, in the case of the third examined example shown in FIG. 16, compared to the first examined example, it is difficult to control the p-type impurity concentration of the p-type semiconductor region AD101 near the interface between the n-type semiconductor region CD and the p-type semiconductor region AD101. The reason is as follows.

When forming the p-type semiconductor region AD101 by ion implantation, the p-type impurity concentration of the p-type semiconductor region AD101 near the bottom surface of the p-type semiconductor region AD101 can be easily controlled by adjusting the dose amount of the ion implantation. In contrast, the p-type impurity concentration of the p-type semiconductor region AD101 at a position away from the bottom surface of the p-type semiconductor region AD101 is likely to fluctuate, and it is difficult to control it to the desired concentration. In the case of the third examined example, compared to the first examined example, the distance from the interface between the n-type semiconductor region CD and the p-type semiconductor region AD101 to the bottom surface of the p-type semiconductor region AD101 is large, making it difficult to control the p-type impurity concentration of the p-type semiconductor region AD101 near the interface between the n-type semiconductor region CD and the p-type semiconductor region AD101. Therefore, in the case of the third examined example, compared to the first examined example, the withstand voltage of the Zener diode is likely to fluctuate. In order to improve the reliability of the semiconductor device, it is necessary to prevent the withstand voltage of the Zener diode from fluctuating.

### Main Features and Effects

The semiconductor device of the present embodiment has the semiconductor substrate SUB, which includes the p-type substrate region (p-type substrate body SB), the n-type buried layer (n-type semiconductor layer) NBL formed on the p-type substrate region, and the p-type semiconductor layer EP formed on the n-type buried layer NBL. The semiconductor device of the present embodiment further includes the DTI region (element isolation region) 5 that penetrates through the semiconductor layer EP and the n-type buried layer NBL and reaches the p-type substrate body SB, the n-type cathode region (n-type semiconductor region CD) of the Zener diode formed in the semiconductor layer EP, and the p-type anode region of the Zener diode formed in the semiconductor layer EP.

One of the main features of the present embodiment is that the p-type anode region of the Zener diode includes the p-type semiconductor region AD1 formed under the n-type semiconductor region CD, and the p-type semiconductor region AD2 formed under the p-type semiconductor region AD1. A PN junction of the Zener diode is formed between the p-type semiconductor region AD1 and the n-type semiconductor region CD. The p-type impurity concentration of the p-type semiconductor region AD2 is higher than the p-type impurity concentration of the p-type semiconductor region AD1.

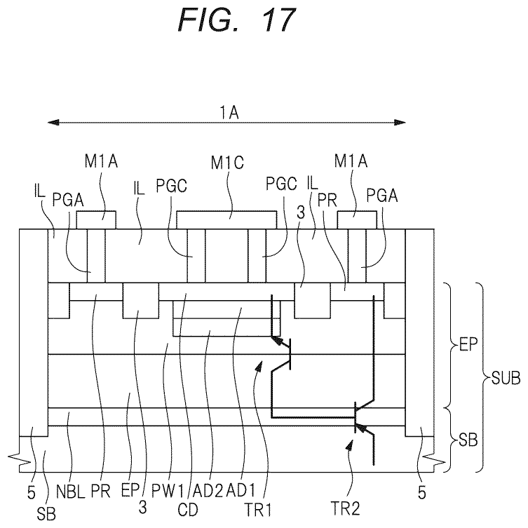

FIG. 17 is an explanatory diagram of the semiconductor device of the present embodiment. The same cross-section as in FIG. 1 is shown in FIG. 17. In FIG. 17, hatching is omitted. Also, FIG. 17 shows a parasitic NPN bipolar transistor TR1 and a parasitic PNP bipolar transistor TR2 formed in the semiconductor device of the present embodiment.

In the semiconductor device of the present embodiment, a parasitic thyristor formed of the parasitic NPN bipolar transistor TR1 and the parasitic PNP bipolar transistor TR2 is formed.

The n-type buried layer NBL functions as an n-type collector region of the parasitic NPN bipolar transistor TR1. A p-type semiconductor region formed of the p-type semiconductor region AD1, the p-type semiconductor region AD2, and the p-type well region PW1 functions as a p-type base region of the parasitic NPN bipolar transistor TR1. The n-type semiconductor region CD functions as an n-type emitter region of the parasitic NPN bipolar transistor TR1. Also, the p-type substrate body SB functions as a p-type collector region of the parasitic PNP bipolar transistor TR2. The n-type buried layer NBL functions as an n-type base region of the parasitic PNP bipolar transistor TR2. A p-type semiconductor region formed of the p-type semiconductor region AD1, the p-type semiconductor region AD2, the p-type well region PW1, and the p-type semiconductor region PR functions as a p-type emitter region of the parasitic PNP bipolar transistor TR2.

In the present embodiment, the p-type semiconductor region AD1 is formed to set the p-type impurity concentration of the p-type semiconductor region AD1 near the interface between the n-type semiconductor region CD and the p-type semiconductor region AD1 to a predetermined design concentration. Here, the design concentration is a concentration that can achieve the required withstand voltage of the Zener diode.

Since the depth of the bottom surface of the p-type semiconductor region AD1 is shallower than the depth of the bottom surface of the p-type semiconductor region AD2, the distance from the interface between the n-type semiconductor region CD and the p-type semiconductor region AD1 to the bottom surface of the p-type semiconductor region AD1 is small. Therefore, by adjusting the dose amount of ion implantation to form the p-type semiconductor region AD1, the p-type impurity concentration of the p-type semiconductor region AD1 near the interface between the n-type semiconductor region CD and the p-type semiconductor region AD1 can be easily set to a predetermined design concentration. Therefore, the withstand voltage of the Zener diode can be set to the required withstand voltage, and the fluctuation of the withstand voltage of the Zener diode can be suppressed.

Then, by forming the p-type semiconductor region AD2, which has a higher p-type impurity concentration than the p-type semiconductor region AD1, under the p-type semiconductor region AD1, the p-type impurity concentration of the p-type anode region under the n-type semiconductor region CD becomes high. This results in an increase in the p-type impurity concentration in the p-type base region of the parasitic NPN bipolar transistor TR1, making it difficult for the parasitic NPN bipolar transistor TR1 to operate. As a result, the operation of the parasitic thyristor can be suppressed or prevented.

That is, in the present embodiment, by forming the p-type semiconductor region AD1 under the n-type semiconductor region CD, the withstand voltage of the Zener diode can be set to the required withstand voltage. By forming the p-type semiconductor region AD2, which has a higher p-type impurity concentration than the p-type semiconductor region AD1, under the p-type semiconductor region AD1, the operation of the parasitic thyristor can be suppressed. Therefore, the performance of the semiconductor device including a Zener diode can be improved. In addition, the reliability of a semiconductor device including a Zener diode can be improved.

Also, when performing ion implantation on the semiconductor substrate SUB, if the dose amount of the ion implantation is large, there is a risk of damage to the semiconductor substrate SUB. The dose amount of ion implantation to form the p-type semiconductor region AD2 in the present embodiment is smaller than the dose amount of ion implantation to form the p-type semiconductor region AD101 in the third examined example. This is because, in the third examined example, it is necessary to set the p-type impurity concentration near the interface between the n-type semiconductor region CD and the p-type semiconductor region AD101 to a predetermined design concentration, so it is necessary to increase the dose amount of ion implantation to form the p-type semiconductor region AD101. On the other hand, in the present embodiment, the p-type impurity concentration near the interface between the n-type semiconductor region CD and the p-type semiconductor region AD1 is adjusted by the dose amount of ion implantation to form the p-type semiconductor region AD1. Therefore, in the present embodiment, the dose amount of ion implantation to form the p-type semiconductor region AD1 and the dose amount of ion implantation to form the p-type semiconductor region AD2 can be made smaller than the dose amount of ion implantation to form the p-type semiconductor region AD101 in the third examined example. Therefore, the damage to the semiconductor substrate SUB can be suppressed or prevented by the ion implantation to form the p-type semiconductor region AD1 and the ion implantation to form the p-type semiconductor region AD2. This can improve the reliability of the semiconductor device.

Also, in the present embodiment, the potential of the n-type buried layer NBL is a floating potential. A structure for supplying power from the wiring Ml and the plug PG to the n-type buried layer NBL is not formed on the semiconductor substrate SUB. That is, the n-type semiconductor region NC1 and the n-type semiconductor region NC2 of the second examined example in FIG. 15 are not formed in the Zener diode formation region 1A in the present embodiment. Therefore, in the case of the present embodiment, the planar dimensions of the Zener diode formation region 1A can be made smaller than in the second examined example. Therefore, the semiconductor device can be miniaturized.

Also, there is a risk that the parasitic thyristor will operate when a potential lower than the potential of the p-type substrate body SB is supplied to the n-type semiconductor region CD, which is the n-type cathode region of the Zener diode, and the p-type well region PW1, which is the p-type anode region. In the present embodiment, by forming the p-type semiconductor region AD1 under the n-type semiconductor region CD and forming the p-type semiconductor region AD2 under the p-type semiconductor region AD1, the operation of the parasitic thyristor can be suppressed or prevented. Therefore, when the potential supplied to the n-type semiconductor region CD from the plug PGC and the potential supplied to the p-type well region PW1 from the plug PGA are lower than the potential of the p-type substrate body SB during the operation of the Zener diode, the semiconductor device of the present embodiment can be applied, and the effect is large.

Also, the potential of the p-type substrate body SB is generally a ground potential. Therefore, when the Zener diode operates, if the potential supplied to the n-type semiconductor region CD from the plug PGC and the potential supplied to the p-type well region PW1 from the plug PGA are both negative, the semiconductor device of the present embodiment can be applied, and the effect is significant.

Also, when the Zener diode operates in the forward direction, the parasitic thyristor is more likely to operate than when the Zener diode operates in the reverse direction. Therefore, when the Zener diode operates, if the potential supplied to the p-type well region PW1 from the plug PGA is higher than the potential supplied to the n-type semiconductor region CD from the plug PGC, the semiconductor device of the present embodiment can be applied, and the effect is significant.

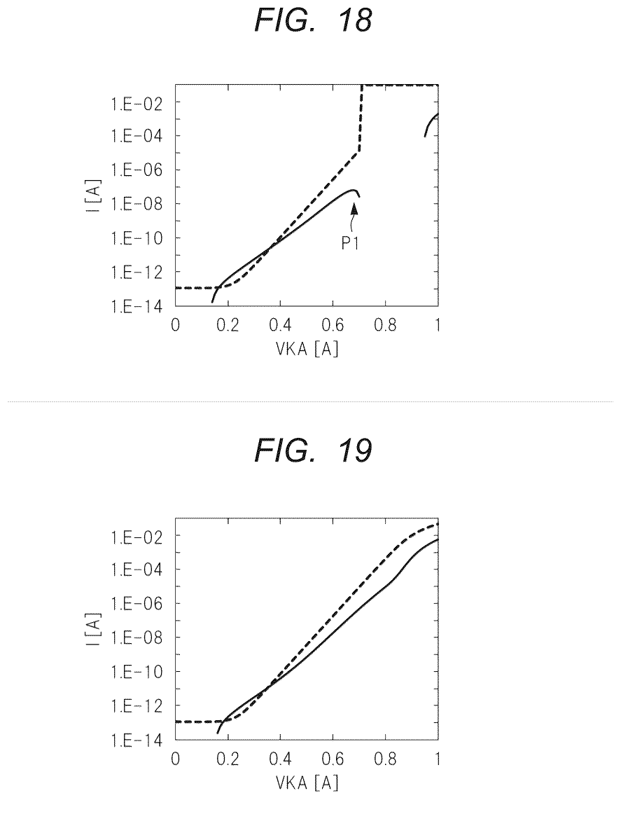

FIG. 18 is a graph showing the operating characteristics of the Zener diode of the first examined example. FIG. 19 is a graph showing the operating characteristics of the Zener diode of the present embodiment. In each of FIGS. 18 and 19, the voltage VKA on the horizontal axis of the graph represents the difference between the anode voltage and the cathode voltage, and the vertical axis of the graph represents the current value. FIGS. 18 and 19 show the operating characteristics when the anode potential and the cathode potential are both negative, and the anode potential is higher than the cathode potential. Also, in each of FIGS. 18 and 19, the anode current of the Zener diode is shown by a solid line, and the substrate current is shown by a dotted line. The anode current is the forward current of the Zener diode. The substrate current flows from the p-type substrate body SB to the semiconductor layer EP.

In the case of the first examined example shown in FIG. 18, the parasitic thyristor starts to operate at the operating point P1 shown in the graph. When the voltage VKA is greater than the operating point P1, the substrate current flowing from the p-type substrate body SB to the semiconductor layer EP rapidly increases due to the operation of the parasitic thyristor. As a result, the anode current of the Zener diode flows backward, and the current no longer flows from the anode region to the cathode region. As a result, the normal operation of the Zener diode is inhibited.

On the other hand, in the case of the present embodiment shown in FIG. 19, the parasitic thyristor is not operating. That is, the operating point P1 shown in the graph of FIG. 18 is not present in the graph of FIG. 19. Therefore, the Zener diode operates normally.

### Second Embodiment

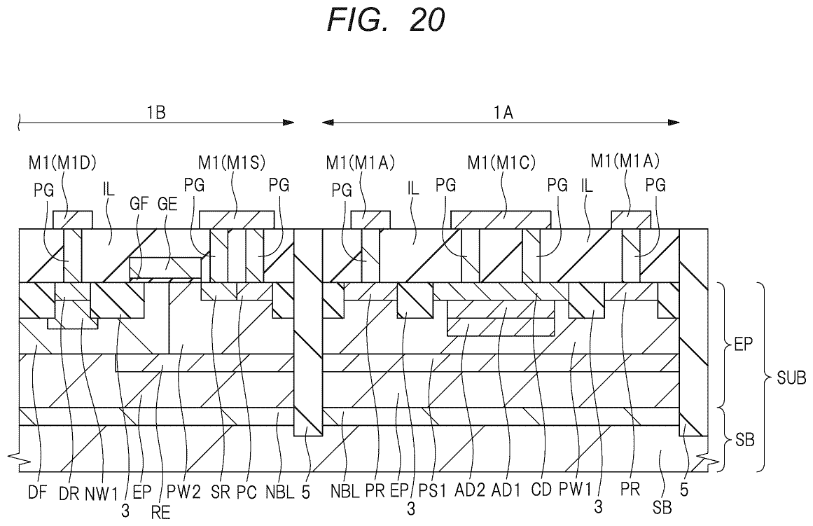

FIG. 20 is a main portion cross-sectional view of the semiconductor device of the second embodiment. FIG. 20 shows a cross-section corresponding to the above-mentioned FIG. 13.

As shown in FIG. 20, the semiconductor device of the second embodiment has a p-type semiconductor region PS1 and a p-type resurf layer RE.

As shown in FIG. 20, in the Zener diode formation region 1A, the p-type semiconductor region PS1 is formed in the semiconductor layer EP. The p-type semiconductor region PS1 is located under the p-type well PW1. That is, the p-type semiconductor region PS1 is formed in the p-type semiconductor layer EP under the p-type well PW1. In the second embodiment, in the direction from the main surface to the back surface of the semiconductor substrate SUB, the p-type well PW1 and the p-type semiconductor region PS1 are adjacent to each other. The p-type semiconductor region PS1 is separated from the n-type buried layer NBL. The impurity concentration of the p-type semiconductor region PS1 is higher than the impurity concentration of the p-type semiconductor layer EP under the p-type semiconductor region PS1.

In the transistor formation region 1B, the p-type resurf layer RE is formed in the semiconductor layer EP. The p-type resurf layer RE is formed under the p-type well region PW2 and the n-type drift region DF.

The p-type semiconductor region PS1 and the p-type resurf layer RE can be formed by the same ion implantation step, thereby suppressing the number of manufacturing steps of the semiconductor device. For example, before forming the p-type semiconductor region AD1 and the p-type semiconductor region AD2, the p-type semiconductor region PS1 and the p-type resurf layer RE can be formed using an ion implantation method.

The other configurations of the semiconductor device of the second embodiment are the same as those of the semiconductor device of the first embodiment.

In the second embodiment, the p-type semiconductor region PS1 having a higher p-type impurity concentration than the p-type semiconductor layer EP is formed in the p-type semiconductor layer EP under the p-type well region PW1. By forming the p-type semiconductor region PS1, the p-type impurity concentration of the p-type base region of the parasitic NPN bipolar transistor TR1 becomes even higher, making it more difficult for the parasitic NPN bipolar transistor TR1 to operate. As a result, it is possible to further suppress the operation of the parasitic thyristor in the Zener diode formation region 1A.

### Third Embodiment

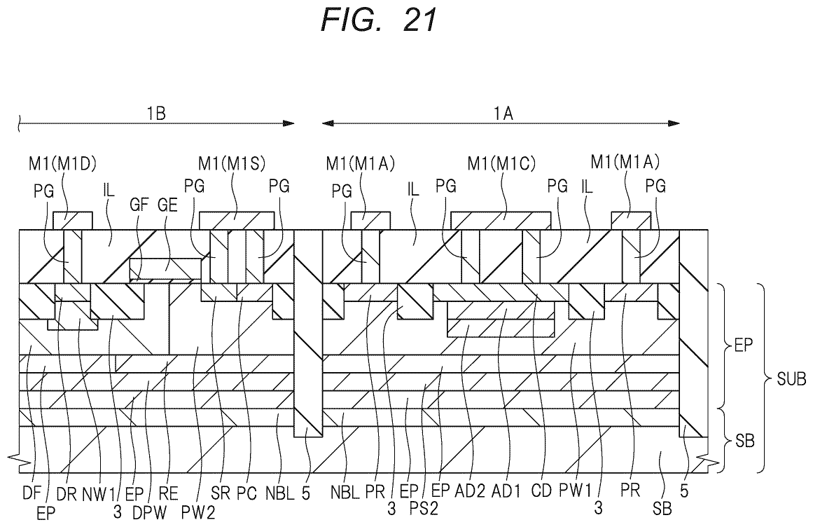

FIG. 21 is a main portion cross-sectional view of the semiconductor device of the third embodiment. The cross-section corresponding to FIGS. 13 and 20 is shown in FIG. 21.

As shown in FIG. 21, the semiconductor device of the third embodiment has a p-type semiconductor region PS2, the p-type resurf layer RE, and a p-type well region DPW.

As shown in FIG. 21, in the Zener diode formation region 1A, the p-type semiconductor region PS2 is formed in the semiconductor layer EP. The p-type semiconductor region PS2 is located under the p-type well PW1. That is, the p-type semiconductor region PS2 is formed in the p-type semiconductor layer EP under the p-type well PW1. In the third embodiment, the p-type semiconductor region PS2 is separated from the p-type well PW1 and the n-type buried layer NBL. The impurity concentration of the p-type semiconductor region PS2 is higher than the impurity concentration of the p-type semiconductor layer EP under the p-type semiconductor region PS2. Also, the impurity concentration of the p-type semiconductor region PS2 is higher than the impurity concentration of the p-type semiconductor layer EP between the p-type semiconductor region PS2 and the p-type well PW1.

In the transistor formation region 1B, the p-type RESURF layer RE and the p-type well region DPW are formed in the semiconductor layer. The p-type RESURF layer RE is formed under the p-type well region PW2 and the n-type drift region DF. The p-type well region DPW is formed under the p-type RESURF layer RE.

The p-type semiconductor region PS2 and the p-type well region DPW can be formed by the same ion implantation step, thereby reducing the number of manufacturing steps of the semiconductor device. For example, before forming the p-type semiconductor region AD1 and the p-type semiconductor region AD2, the p-type semiconductor region PS2, the p-type RESURF layer RE, and the p-type well region DPW can be formed using an ion implantation method.

The other configurations of the semiconductor device of the third embodiment are the same as those of the semiconductor device of the first embodiment.

In the third embodiment, the p-type semiconductor region PS2 having a higher p-type impurity concentration than the p-type semiconductor layer EP is formed in the p-type semiconductor layer EP under the p-type well region PW1. The formation of the p-type semiconductor region PS2 further increases the p-type impurity concentration of the p-type base region of the parasitic NPN bipolar transistor TR1, making it more difficult for the parasitic NPN bipolar transistor TR1 to operate. As a result, the operation of the parasitic thyristor can be further suppressed in the Zener diode formation region 1A.

### Fourth Embodiment

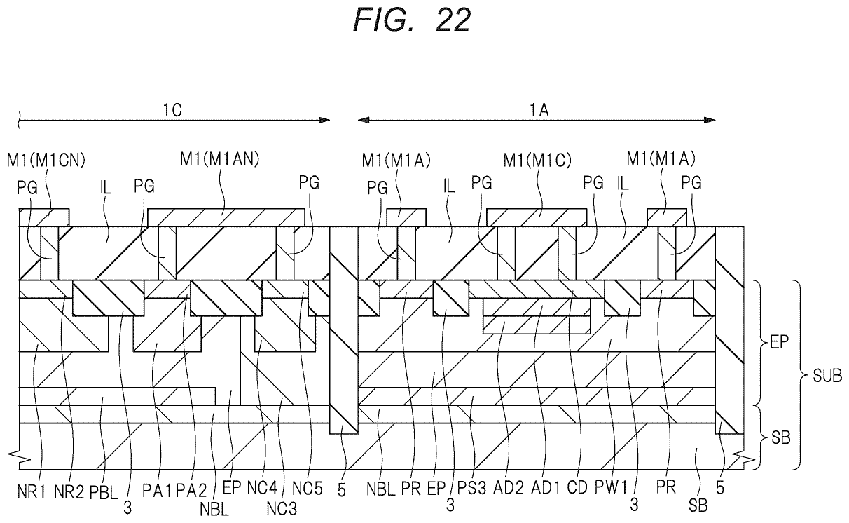

FIG. 22 is a main portion cross-sectional view of the semiconductor device of the fourth embodiment. FIG. 22 shows the cross-section of the Zener diode formation region 1A and a diode formation region 1C. The cross-section of the Zener diode formation region 1A in FIG. 22 corresponds to the cross-section of the Zener diode formation region 1A in FIGS. 1 and 13.

As shown in FIG. 22, the semiconductor device of the fourth embodiment has a p-type semiconductor region PS3.

As shown in FIG. 22, in the Zener diode formation region 1A, the p-type semiconductor region PS3 is formed in the semiconductor layer EP. The p-type semiconductor region PS3 is located under the p-type well PW1. That is, the p-type semiconductor region PS3 is formed in the p-type semiconductor layer EP under the p-type well PW1. In the fourth embodiment, in the direction from the main surface to the back surface of the semiconductor substrate SUB, the p-type semiconductor region PS3 and the n-type buried layer NBL are adjacent to each other. The p-type semiconductor region PS3 is separated from the p-type well PW1. The impurity concentration of the p-type semiconductor region PS3 is higher than the impurity concentration of the p-type semiconductor layer EP on the p-type semiconductor region PS3.

The other configurations of the diode formation region 1A in the fourth embodiment are the same as those of the diode formation region 1A in the first embodiment.

In the fourth embodiment, a diode element is formed in the diode formation region 1C. Specifically, as shown in FIG. 22, the semiconductor device of the fourth embodiment has an n-type semiconductor region NR1, an n-type semiconductor region NR2, an n-type semiconductor region NC3, an n-type semiconductor region NC4, an n-type semiconductor region NC5, the p-type semiconductor region PA1, the p-type semiconductor region PA2, and a p-type buried layer PBL.

In the diode formation region 1C, the n-type semiconductor region NR1, the n-type semiconductor region NR2, the n-type semiconductor region NC3, the n-type semiconductor region NC4, the n-type semiconductor region NC5, the p-type semiconductor region PA1, the p-type semiconductor region PA2, and the p-type buried layer PBL are formed in the p-type semiconductor layer EP.

The n-type semiconductor region formed of the n-type semiconductor region NR1 and the n-type semiconductor region NR2 functions as the n-type cathode region of the diode. The n-type semiconductor region NR1 is formed under the n-type semiconductor region NR2. The n-type impurity concentration of the n-type semiconductor region NR2 is higher than the n-type impurity concentration of the n-type semiconductor region NR1. The plug PG is disposed on the n-type semiconductor region NR2, and the plug PG is electrically connected to the n-type semiconductor region NR2.

A p-type semiconductor region, formed of the p-type semiconductor region PA1, the p-type semiconductor region PA2, and the p-type semiconductor layer EP, functions as a p-type anode region of the diode. The p-type semiconductor region PA1 is formed under the p-type semiconductor region PA2. The p-type impurity concentration of the p-type semiconductor region PA2 is higher than the p-type impurity concentration of the p-type semiconductor region PA1, and the p-type impurity concentration of the p-type semiconductor region PA1 is higher than the p-type impurity concentration of the p-type semiconductor layer EP. The plug PG is disposed on the p-type semiconductor region PA2, and this plug PG is electrically connected to the p-type semiconductor region PA2.

The n-type semiconductor region NC4 is formed under the n-type semiconductor region NC5, and the n-type semiconductor region NC3 is formed under the n-type semiconductor region NC4. The n-type semiconductor region NC3 is in contact with the n-type buried layer NBL. The n-type impurity concentration of the n-type semiconductor region NC5 is higher than the n-type impurity concentration of the n-type semiconductor region NC4, and the n-type impurity concentration of the n-type semiconductor region NC4 is higher than the n-type impurity concentration of the n-type semiconductor region NC3. The plug PG is disposed on the n-type semiconductor region NC5, and this plug PG is electrically connected to the n-type semiconductor region NC5.

The p-type buried layer PBL is formed on the n-type buried layer NBL. In the direction from the main surface to the back surface of the semiconductor substrate SUB, the p-type buried layer PBL and the n-type buried layer NBL are adjacent to each other. The p-type impurity concentration of the p-type buried layer PBL is higher than the p-type impurity concentration of the p-type semiconductor layer EP.

A cathode potential is supplied to the n-type semiconductor region NR2 via the plug PG from a wiring M1CN. An anode potential is supplied to the p-type semiconductor region PA2 via the plug PG from a wiring M1AN. And, the anode potential is supplied to the n-type buried layer NBL via the plug PG and the n-type semiconductor regions NC5, NC4, and NC3 from the wiring M1AN. Therefore, in the diode formation region 1C, the potential of the p-type anode region and the potential of the n-type buried layer NBL are the same. This prevents the parasitic thyristor from operating in the diode formation region 1C.

The p-type semiconductor region PS3 of the Zener diode formation region 1A and the p-type buried layer PBL of the diode formation region 1C can suppress the number of manufacturing steps of the semiconductor device by forming them by the same ion implantation step.

In the present fourth embodiment, in the Zener diode formation region 1A, the p-type semiconductor region PS3 having a higher p-type impurity concentration than the p-type semiconductor layer EP is formed in the p-type semiconductor layer EP under the p-type well region PW1. By forming the p-type semiconductor region PS3, the p-type impurity concentration of the p-type base region of the parasitic NPN bipolar transistor TR1 becomes even higher, making it more difficult for the parasitic NPN bipolar transistor TR1 to operate. As a result, it is possible to further suppress the operation of the parasitic thyristor in the Zener diode formation region 1A.

### Fifth Embodiment

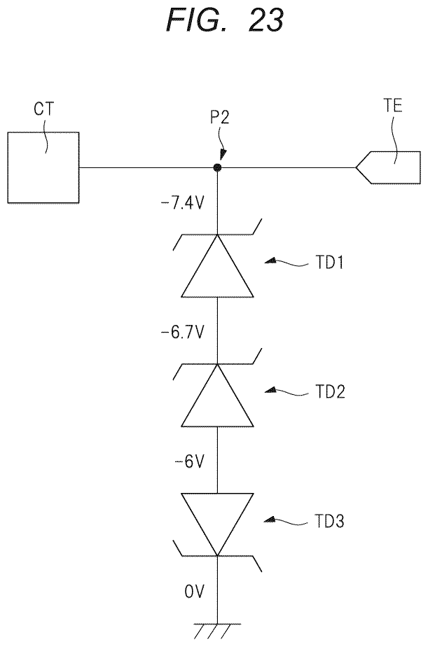

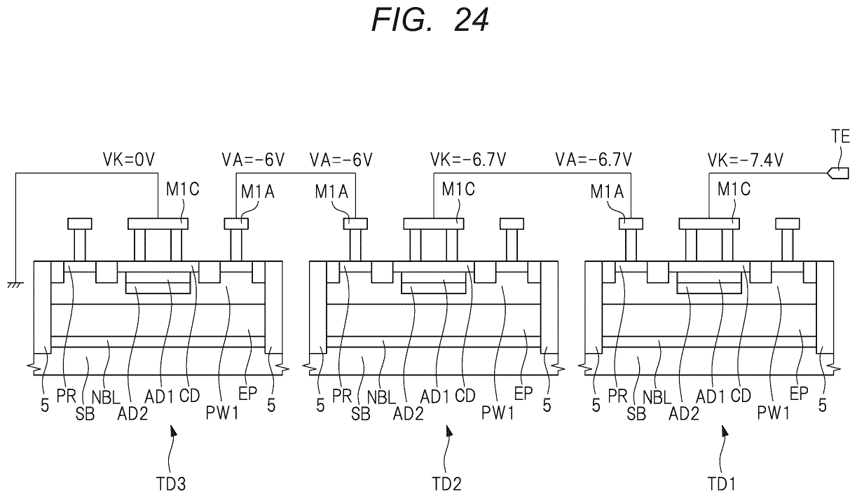

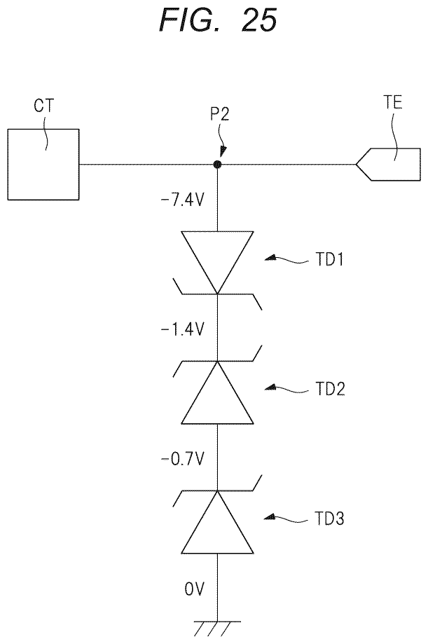

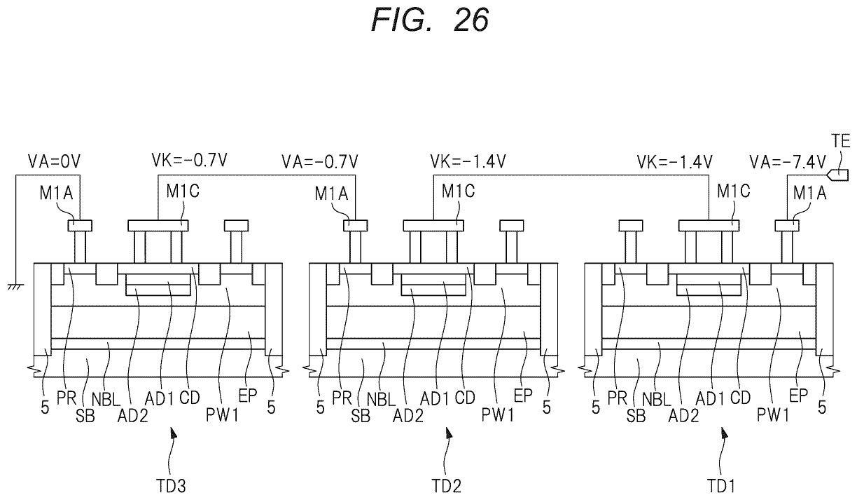

FIGS. 23, 24, 25, and 26 are explanatory diagrams showing usage examples of the semiconductor device. Circuit examples using Zener diodes TD1, TD2, TD3 are shown in each of FIGS. 23 and 25. The connection relationships of the Zener diodes TD1, TD2, TD3 are shown in each of FIGS. 24 and 26. The connection relationship of the Zener diodes TD1, TD2, TD3 shown in FIG. 24 is the same as the connection relationship of the Zener diodes TD1, TD2, TD3 shown in the circuit diagram of FIG. 23. Also, the connection relationship of the Zener diodes TD1, TD2, TD3 shown in FIG. 26 is the same as the connection relationship of the Zener diodes TD1, TD2, TD3 shown in the circuit diagram of FIG. 25. FIGS. 23, 24, 25, and 26 also show voltage examples when a negative surge voltage occurs.

As shown in FIGS. 23 and 25, one end of the series circuit of the Zener diodes TD1, TD2, TD3 is connected to the connection point P2 between an input terminal TE and a circuit CT to be protected. The other end of the series circuit of the Zener diodes TD1, TD2, TD3 is connected to the ground potential. Accordingly, when a negative surge voltage is applied from the input terminal TE to the circuit CT to be protected, the Zener diodes TD1, TD2, TD3 operate, allowing current to flow from the input terminal TE to the ground via the Zener diodes TD1, TD2, TD3. As a result, it is possible to protect the circuit CT when a negative surge voltage occurs at the input terminal TE.

Among the series-connected Zener diodes TD1, TD2, TD3, the Zener diode TD1 is connected to the input terminal TE, the Zener diode TD3 is connected to the ground potential, and the Zener diode TD2 is disposed between the Zener diode TD1 and the Zener diode TD3.

In the case of FIGS. 23 and 24, the cathode (cathode wiring M1C) of the Zener diode TD1 is connected to the input terminal TE. The anode (anode wiring M1A) of the Zener diode TD1 is connected to the cathode (cathode wiring M1C) of the Zener diode TD2. The anode (anode wiring M1A) of the Zener diode TD2 is connected to the anode (anode wiring M1A) of the Zener diode TD3. And the cathode (cathode wiring M1C) of the Zener diode TD3 is connected to the ground potential.

In the case of FIGS. 23 and 24, when a negative surge voltage occurs at the input terminal TE, the negative surge voltage is applied to the cathode (cathode wiring M1C) of the Zener diode TD1 via the connection point P2. As a result, the Zener diodes TD1, TD2 operate in the forward direction, and the Zener diode TD3 operates in the reverse direction. In the reverse operating Zener diode TD3, the difference between the anode voltage VA and the cathode voltage VK is, for example, 6 V, and in each of the forward operating Zener diodes TD1, TD2, the difference between the anode voltage VA and the cathode voltage VK is, for example, 0.7 V.

Note that when the anode voltage VA is higher than the cathode voltage VK, the Zener diode operates in the forward direction, and when the anode voltage VA is lower than the cathode voltage VK, the Zener diode operates in the reverse direction.

In the case of FIGS. 25 and 26, the anode (anode wiring M1A) of the Zener diode TD1 is connected to the input terminal TE. The cathode (cathode wiring M1C) of the Zener diode TD1 is connected to the cathode (cathode wiring M1C) of the Zener diode TD2. The anode (anode wiring M1A) of the Zener diode TD2 is connected to the cathode (cathode wiring M1C) of the Zener diode TD3. And the anode (anode wiring M1A) of the Zener diode TD3 is connected to the ground potential.

In the case of FIGS. 25 and 26, when a negative surge voltage occurs at the input terminal TE, the negative surge voltage is applied to the anode (anode wiring M1A) of the Zener diode TD1 via the connection point P2. As a result, the Zener diode TD1 operates in the reverse direction, and the Zener diodes TD2, TD3 operate in the forward direction. In the reverse operating Zener diode TD1, the difference between the anode voltage VA and the cathode voltage VK is, for example, 6 V, and in each of the forward operating Zener diodes TD2, TD3, the difference between the anode voltage VA and the cathode voltage VK is, for example, 0.7 V.

In the case of FIGS. 23 and 24, in the Zener diode TD3, the cathode voltage VK and the potential of the p-type substrate body SB are the same, and also, since the anode voltage VA is lower than the cathode voltage VK, the parasitic thyristor does not operate.

In the case of FIGS. 23 and 24, in the Zener diodes TD1 and TD2, both the anode voltage VA and the cathode voltage VK are negative, and also, since the anode voltage VA is higher than the cathode voltage VK, there is a possibility that the parasitic thyristor operates.

In the case of FIGS. 25 and 26, in the Zener diode TD3, since the anode voltage VK and the potential of the p-type substrate body SB are the same, the parasitic PNP bipolar transistor TR2 does not operate. Therefore, in the Zener diode TD3, the parasitic thyristor does not operate.

In the case of FIGS. 25 and 26, in the Zener diodes TD1 and TD2, since both the anode voltage VA and the cathode voltage VK are negative, there is a possibility that the parasitic thyristor operates. However, when the anode voltage VA is lower than the cathode voltage VK, the parasitic thyristor is less likely to operate compared to when the anode voltage VA is higher than the cathode voltage VK.

Therefore, in the case of FIGS. 23 and 24, it is feared that the parasitic thyristor operates in the Zener diodes TD1 and TD2. On the other hand, in the case of FIGS. 25 and 26, it is feared that the parasitic thyristor operates in the Zener diode TD2.

The Zener diodes TD1, TD2, and TD3 have the structure of the Zener diode formation region 1A in any of the first embodiment, the second embodiment, the third embodiment, and the fourth embodiment. Therefore, even in the Zener diodes TD1 and TD2 in the case of FIGS. 23 and 24, it is possible to suppress the operation of the parasitic thyristor. Also, even in the Zener diode TD2 in the case of FIGS. 25 and 26, it is possible to suppress the operation of the parasitic thyristor.

Here, the Zener diodes TD1 and TD2 in FIGS. 23 and 24 and the Zener diode TD2 in FIGS. 25 and 26 are compared. In the Zener diode TD1 of FIGS. 23 and 24, the potential difference between the p-type substrate body SB and the cathode region is −7.4 V. In the Zener diode TD2 of FIGS. 23 and 24, the potential difference between the p-type substrate body SB and the cathode region is −6.7 V. On the other hand, in the Zener diode TD2 of FIGS. 25 and 26, the potential difference between the p-type substrate body SB and the cathode region is −1.4 V. The larger the absolute value of the potential difference between the p-type substrate body SB and the cathode region, the easier the parasitic thyristor operates. Therefore, compared to the Zener diodes TD1 and TD2 in FIGS. 23 and 24, the parasitic thyristor is less likely to operate in the Zener diode TD2 in FIGS. 25 and 26. As a result, when comparing the Zener diodes TD1, TD2, and TD3 in FIGS. 23 and 24 with the Zener diodes TD1, TD2, and TD3 in FIGS. 25 and 26, it is easier to prevent the operation of the parasitic thyristor in the Zener diodes TD1, TD2, and TD3 in FIGS. 25 and 26. Therefore, by using the circuit configuration shown in FIGS. 25 and 26, it is possible to reliably protect the circuit CT when a negative surge voltage is generated at the input terminal TE.

The invention made by the present inventor has been described above in detail based on the embodiment, but the present invention is not limited to the embodiment described above, and it is needless to say that various modifications can be made without departing from the gist thereof.

What is claimed is:

1. A semiconductor device comprising:
a semiconductor substrate comprising:
a substrate region of a first conductivity type;
a first semiconductor layer of a second conductivity type opposite the first conductivity type formed on the substrate region; and
a second semiconductor layer of the first conductivity type formed on the first semiconductor layer;
an element isolation region penetrating through the second semiconductor layer and the first semiconductor layer and reaching the substrate region;
a cathode region of the second conductivity type of a Zener diode, the cathode region being formed in the second semiconductor layer; and
an anode region of the first conductivity type of the Zener diode, the anode region being formed in the second semiconductor layer,
wherein the anode region comprises:
a first semiconductor region of the first conductivity type formed under the cathode region; and
a second semiconductor region of the first conductivity type formed under the first semiconductor region,
wherein a first PN junction is formed between the first semiconductor region and the cathode region, and
wherein an impurity concentration of the second semiconductor region is higher than an impurity concentration of the first semiconductor region.

2. The semiconductor device according to claim 1,
wherein the anode region comprises a third semiconductor region of the first conductivity type covering a side surface of the first semiconductor region, a side surface of the second semiconductor region, and a bottom surface of the second semiconductor region, and
wherein the impurity concentration of the first semiconductor region is higher than an impurity concentration of the third semiconductor region.

3. The semiconductor device according to claim 2,
wherein the cathode region is disposed adjacent to the first semiconductor region and the third semiconductor region, and
wherein a second PN junction is formed between the third semiconductor region and the cathode region.

4. The semiconductor device according to claim 3,
wherein the impurity concentration of the third semiconductor region is higher than an impurity concentration of the second semiconductor layer.

5. The semiconductor device according to claim 3, comprising:
a first plug disposed on the cathode region and electrically connected to the cathode region; and
a second plug electrically connected to the anode region.

6. The semiconductor device according to claim 5,
wherein a first potential is supplied from the first plug to the cathode region,
wherein a second potential is supplied from the second plug to the anode region, and
wherein the first potential and the second potential are lower than a potential of the substrate region.

7. The semiconductor device according to claim 6,
wherein the first potential and the second potential are negative potentials.

8. The semiconductor device according to claim 6,
wherein the second potential is higher than the first potential.

9. The semiconductor device according to claim 5, comprising:
a fourth semiconductor region of the first conductivity type formed in the third semiconductor region,
wherein the second plug is disposed on the fourth semiconductor region and electrically connected to the third semiconductor region via the fourth semiconductor region.

10. The semiconductor device according to claim 1,
wherein the cathode region and the anode region are surrounded by the element isolation region.

11. The semiconductor device according to claim 1,
wherein a potential of the first semiconductor layer is a floating potential.

12. The semiconductor device according to claim 4, comprising:
a fifth semiconductor region of the first conductivity type formed in the second semiconductor layer and located under the third semiconductor region,
wherein an impurity concentration of the fifth semiconductor region is higher than the impurity concentration of the second semiconductor layer.

13. A method of manufacturing a semiconductor device including a Zener diode, the method comprising:
(a) preparing a semiconductor substrate, the semiconductor substrate comprising:
a substrate region of a first conductivity type;
a first semiconductor layer of a second conductivity type opposite the first conductivity type formed on the substrate region; and
a second semiconductor layer of the first conductivity type formed on the first semiconductor layer;
(b) forming an anode region of the first conductivity type of the Zener diode in the second semiconductor layer; and
(c) forming a cathode region of the second conductivity type of the Zener diode in the second semiconductor layer,
wherein the (b) comprises:
(b1) forming a mask layer on the semiconductor substrate;
(b2) after the (b1), forming a first semiconductor region of the first conductivity type of the anode region in the first semiconductor layer by a first ion implantation;
(b3) after the (b1), forming a second semiconductor region of the first conductivity type of the anode region in the first semiconductor layer by a second ion implantation; and
(b4) after the (b2) and the (b3), removing the mask layer,
wherein an implantation energy of the second ion implantation is higher than an ion implantation energy of the first ion implantation,
wherein an impurity concentration of the second semiconductor region is higher than an impurity concentration of the first semiconductor region,
wherein after the (b2) and the (b3), the second semiconductor region is located under the first semiconductor region, and wherein after the (b2) and the (c), the first semiconductor region is located under the cathode region, and a first PN junction is formed between the first semiconductor region and the cathode region.

14. The method according to claim 13,
wherein a dose amount of the second ion implantation is greater than a dose amount of the first ion implantation.

15. The method according to claim 13, comprising:
(d) forming an element isolation region, the element isolation region penetrating through the second semiconductor layer and the first semiconductor layer and reaching the substrate region.

16. The method according to claim 13,
wherein the (b) comprises:
(b5) forming a third semiconductor region of the first conductivity type of the anode region in the first semiconductor layer by a third ion implantation,
wherein the third semiconductor region covers a side surface of the first semiconductor region, a side surface of the second semiconductor region, and a bottom surface of the second semiconductor region, and
wherein the impurity concentration of the first semiconductor region is higher than an impurity concentration of the third semiconductor region.
